(19) United States
(12) Patent Application Publication
(10) Pub. No.: US 2026/0314290 A1
(43) Pub. Date: Oct. 8, 2026

(54) APPARATUS AND METHOD FOR REMOVAL OF OXIDE AND CARBON FROM SEMICONDUCTOR FILMS IN A SINGLE PROCESSING CHAMBER

(71) Applicant: ASM IP Holding B.V., Almere (NL)

(72) Inventors: Xing Lin, Chandler, AZ (US); Peipei Gao, Tempe, AZ (US); Fei Wang, Tempe, AZ (US); John Tolle, Gilbert, AZ (US); Bubesh Babu Jotheeswaran, Gilbert, AZ (US); Vish Ramanathan, Tempe, AZ (US); Eric Hill, Groveland, MA (US)

(21) Appl. No.: 19/709,758

(22) Filed: Jun. 16, 2026

Related U.S. Application Data
(63) Continuation of application No. 17/875,907, filed on Jul. 28, 2022, now Pat. No. 12,685,061.
Application No. 17/875,907 is a division of application No. 16/000,109, filed on Jun. 5, 2018, now abandoned.
(60) Provisional application No. 62/532,248, filed on Jul. 13, 2017.

(51) Int. Cl. H10P 70/00; B08B 5/00; B08B 7/00; H01J 37/32; H10P 50/28; H10P 72/00

(52) U.S. Cl. CPC H10P 70/12; B08B 5/00; B08B 7/0035; H01J 37/32357; H01J 37/32449; H10P 50/287; H10P 72/0402

(57) ABSTRACT

A system and method for removing both carbon-based contaminants and oxygen-based contaminants from a semiconductor substrate within a single process chamber is disclosed. The invention may comprise utilization of remote plasma units and multiple gas sources to perform the process within the single process chamber.

### CROSS-REFERENCE TO RELATED PATENT APPLICATION

This application is a continuation of, and claims priority to, U.S. patent application Ser. No. 17/875,907 filed Jul. 28, 2022 titled APPARATUS AND METHOD FOR REMOVAL OF OXIDE AND CARBON FROM SEMICONDUCTOR FILMS IN A SINGLE PROCESSING CHAMBER; which is a divisional of U.S. patent application Ser. No. 16/000,109 filed Jun. 5, 2018 titled APPARATUS AND METHOD FOR REMOVAL OF OXIDE AND CARBON FROM SEMICONDUCTOR FILMS IN A SINGLE PROCESSING CHAMBER; which claims the benefit of U.S. Provisional Patent Application Ser. No. 62/532,248 filed Jul. 13, 2017 titled APPARATUS AND METHOD FOR REMOVAL OF OXIDE AND CARBON FROM SEMICONDUCTOR FILMS IN A SINGLE PROCESSING CHAMBER, the disclosures of which are hereby incorporated by reference in their entirety.

### FIELD OF INVENTION

The present disclosure generally relates to an apparatus and a method for manufacturing electronic devices. More particularly, the disclosure relates to removal of oxide and carbon within semiconductor films formed in a processing chamber.

### BACKGROUND OF THE DISCLOSURE

Prior to the fabrication of semiconductor device, a clean surface of a wafer or substrate is desired. Contaminates on the substrate may adversely affect mechanical and electrical properties of the semiconductor devices formed. It is desired that these contaminates be removed before particular films are deposited onto the substrate.

Contaminants that exist on a silicon or silicon germanium substrate may include carbon-based contaminants, such as carbonaceous contaminants and hydrocarbon contaminates. Other contaminants may include oxygen-based contaminants, such as native oxides, for example. It may be imperative to remove these contaminants before epitaxial processes can take place.

Prior approaches to contaminant removal focus on removing one of the contaminants, either carbon-based or oxygen-based, but not both. This may be in part due to equipment limitations of the prior approaches. As a result, a system and method to remove both carbon-based and oxygen-based contaminants is desired.

### BRIEF DESCRIPTION OF THE DRAWING FIGURES

These and other features, aspects, and advantages of the invention disclosed herein are described below with reference to the drawings of certain embodiments, which are intended to illustrate and not to limit the invention.

FIG. 1 is a cross-sectional illustration of a system in accordance with at least one embodiment of the invention.

FIG. 2 is a cross-sectional illustration of a system in accordance with at least one embodiment of the invention.

FIGS. 3A, 3B and 3C are flowcharts of methods in accordance with at least one embodiment of the invention.

FIG. 4 is a flowchart of a step in accordance with at least one embodiment of the invention.

FIG. 5 is a flowchart of a step in accordance with at least one embodiment of the invention.

FIG. 6 is a flowchart of a step in accordance with at least one embodiment of the invention.

### DETAILED DESCRIPTION OF EXEMPLARY EMBODIMENTS

Although certain embodiments and examples are disclosed below, it will be understood by those in the art that the invention extends beyond the specifically disclosed embodiments and/or uses of the invention and obvious modifications and equivalents thereof. Thus, it is intended that the scope of the invention disclosed should not be limited by the particular disclosed embodiments described below.

Embodiments of the invention are directed to a system with a single process chamber having a capability to remove both carbon-based contaminants and oxygen-based contaminants. The embodiments have several advantages over prior approaches including: (1) incorporation of at least one remote plasma unit (RPU) with the ability to generate both hydrogen radicals and fluorine radicals; and (2) compatibility of the process chamber with both hydrogen radicals and fluorine radicals.

Embodiments of the invention may be used to clean semiconductor substrates made of at least one of the following materials: silicon; silicon germanium; or germanium, for example. In one embodiment, the percentage of germanium in silicon germanium may vary from 10% to 90%. Also, embodiments of the invention may be used to etch carbon layers, such as an advanced patterning film (APF); photoresists; or other carbon contaminations including CHFₓ, SiC, or SiOC. In addition, embodiments of the invention may be used to clean a surface of dielectric materials, such as silicon oxide, silicon nitride, silicon oxynitride, fluorinated silicon oxide, silicon carboxide, and silicon carboxynitride. Furthermore, embodiments of the invention may be applied to patterned wafer surfaces.

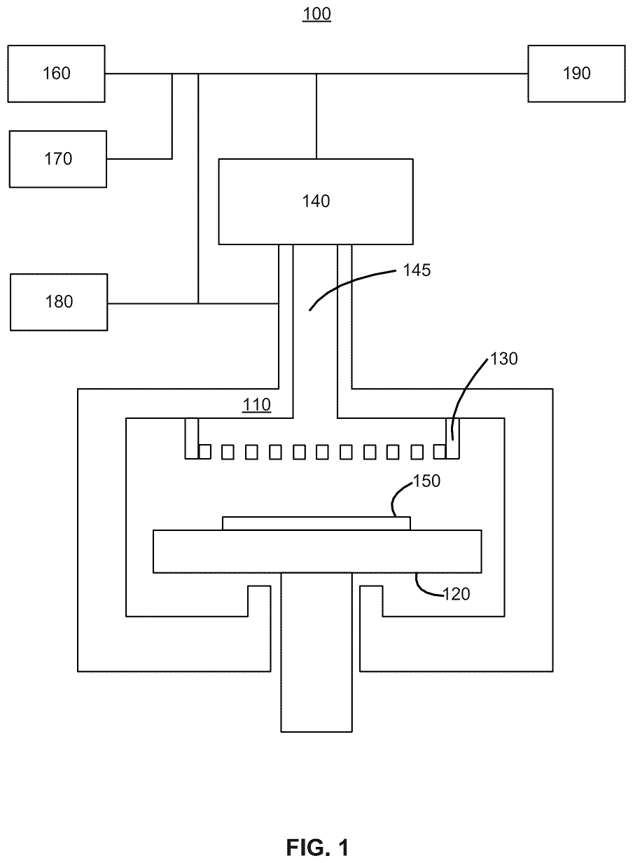

FIG. 1 illustrates a system 100 in accordance with at least one embodiment of the invention. The system 100 may comprise a reaction chamber 110, a susceptor 120, a showerhead 130, a remote plasma unit 140, and a transport path 145 between the remote plasma unit 140 and the reaction chamber 110. A substrate 150 is placed on the susceptor 120 for processing.

The reaction chamber 110 defines a space in which the substrate 150 is processed. The reaction chamber 110, the susceptor 120, the showerhead 130, and the transport path 145 may be coated with materials or bulk ceramic material in order to allow for compatibility with different radicals. The materials for coating may include at least one of: anodized aluminum oxide (Al₂O₃); atomic layer deposition (ALD)-formed aluminum oxide; plasma sprayed Al₂O₃; bare aluminum parts with native aluminum oxide, yttrium oxide (Y₂O₃); yttrium oxide stabilized zirconium oxide (YSZ); zirconium oxide (ZrO₂); lanthanum zirconium oxide (LZO); yttrium aluminum garnet (YAG); yttrium oxyfluoride (YOF); combination of the above materials; or the above substrate doped with other glass phase materials. In some cases, the coating materials can be made with two layers. For example, the first layer may be coated with anodized Al₂O₃ and the second layer may be coated with ALD-formed Al₂O₃. The coating may be amorphous phase, crystalline phase, or mixed. The bulk ceramic material may include: aluminum oxide (Al₂O₃); zirconium oxide (ZrO₂); yttrium oxide (Y₂O₃); or yttrium oxide stabilized zirconium oxide (YSZ).

The system 100 also may comprise a first gas source 160, a second gas source 170, a third gas source 180, and a fourth gas source 190, which all may provide gas to the remote plasma unit 140. The remote plasma unit 140 may comprise a Paragon H* remote plasma unit from MKS Instruments, for example. The third gas source 180 may also be configured to provide gas directly into the reaction chamber 110 without going through the remote plasma unit 140. The first gas source 160 may comprise a source of a precursor gas that produces fluorine radicals, such as NF₃, CF₄, C₂F₆, C₄F₆, C₄F₈, COF₂, SF₆, or WF₆, for example. The second gas source 170 may comprise a source of a gas that produces hydrogen radicals, such as H₂, NH₃, or H₂O, for example. The second gas source 170 may comprise a gas that produces oxygen radicals, such as oxygen or ozone, for example. The third gas source 180 may be a source of NH₃. The fourth gas source 190 may be a source of an inert gas, such as argon, helium, nitrogen, or neon, for example.

The remote plasma unit 140 generates radicals provided from the gas sources. The generated radicals then enter the reaction chamber 110 through the showerhead 130 and then flow onto the substrate 150. The remote plasma source may include: a toroidal style ICP source or a coil style ICP source driven by different RF frequencies, such as a 400 kHz, 2 MHz, 60 MHz and 2.56 GHz microwave source.

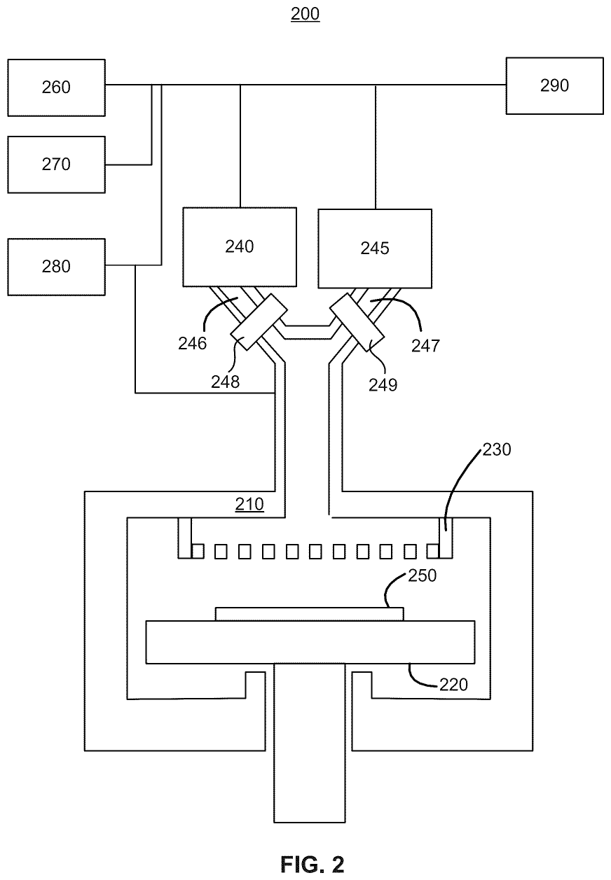

FIG. 2 illustrates a system 200 in accordance with at least one embodiment of the invention. The system 200 may comprise a reaction chamber 210, a susceptor 220, a showerhead 230, a first remote plasma unit 240 dedicating for oxide removal with F*, a second remote plasma unit 245 dedicating for carbon removal with H*, a transport path 246 below the first remote plasma unit, and a transport path 247 below the second remote plasma unit. A substrate 250 is placed on the susceptor 220 for processing. The system 200 may also comprise a first gate vale 248 and a second gate valve 249.

The reaction chamber 210 defines a space in which the substrate 250 is processed. The reaction chamber 210, the susceptor 220, and the showerhead 230 may be coated with materials or bulk ceramic material in order to allow for compatibility with different radicals, such as: anodized aluminum oxide (Al₂O₃); atomic layer deposition (ALD)-formed aluminum oxide; plasma sprayed Al₂O₃; bare aluminum parts with native aluminum oxide; yttrium oxide (Y₂O₃); yttrium oxide stabilized zirconium oxide (YSZ); zirconium oxide (ZrO₂); lanthanum zirconium oxide (LZO); yttrium aluminum garnet (YAG); yttrium oxyfluoride (YOF); combination of the above materials; or the above substrate doped with other glass phase materials. In some cases, the coating materials may be made with two layers. For example, the first layer may be coated with anodized Al₂O₃ and the second layer may be coated with ALD-formed Al₂O₃. The coating may be amorphous phase, crystalline phase, or mixed. The bulk ceramic material may include: aluminum oxide (Al₂O₃); zirconium oxide (ZrO₂); yttrium oxide (Y₂O₃); or yttrium oxide-stabilized zirconium oxide (YSZ). Besides the above coatings and bulk materials for different radicals, materials for the transport path 247 below the second remote plasma unit may also comprise bulk quartz material.

The system 200 also may comprise a first gas source 260, a second gas source 270, a third gas source 280, and a fourth gas source 290, which all may provide gas to the first remote plasma unit 240 and the second remote plasma unit 245. The first remote plasma unit 240 and the second remote plasma unit 245 may comprise a toroidal style ICP source or a coil style ICP source driven by different RF frequencies, such as a 400 kHz, 2 MHz, 60 MHz and 2.56 GHz microwave source, for example. The third gas source 280 may also be configured to provide gas directly into the reaction chamber 210 without going through the first remote plasma unit 240 or the second remote plasma unit 245. The first gas source 260 may comprise a source of a precursor gas that produces fluorine radicals, such as NF₃, CF₄, C₂F₆, C₄F₆, C₄F₈, COF₂, SF₆, or WF₆, for example. The second gas source 270 may comprise a source of gas that produces hydrogen radicals, such as H₂, NH₃, or H₂O, for example. The second gas source 270 may comprise a gas that produces oxygen radicals, such as oxygen or ozone, for example. The third gas source 280 may be a source of NH₃. The fourth gas source 290 may be a source of an inert gas, such as argon, helium, nitrogen, or neon, for example.

The first remote plasma unit 240 (which may be dedicated for F* radicals) and the second remote plasma unit 245 (which may be dedicated for H* radicals) generate radicals provided from the gas sources. The generated radicals then enter the reaction chamber 210 through the showerhead 230 and then flow onto the substrate 250. To prevent radicals generated by one remote plasma unit back streaming into the second remote plasma, the gate valves 248 and 249 may be located at the outlet of RPU.

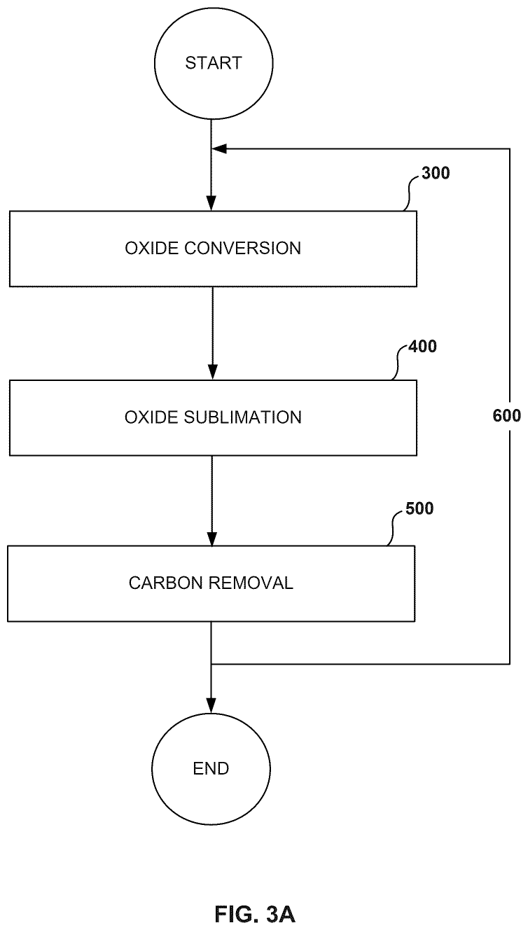

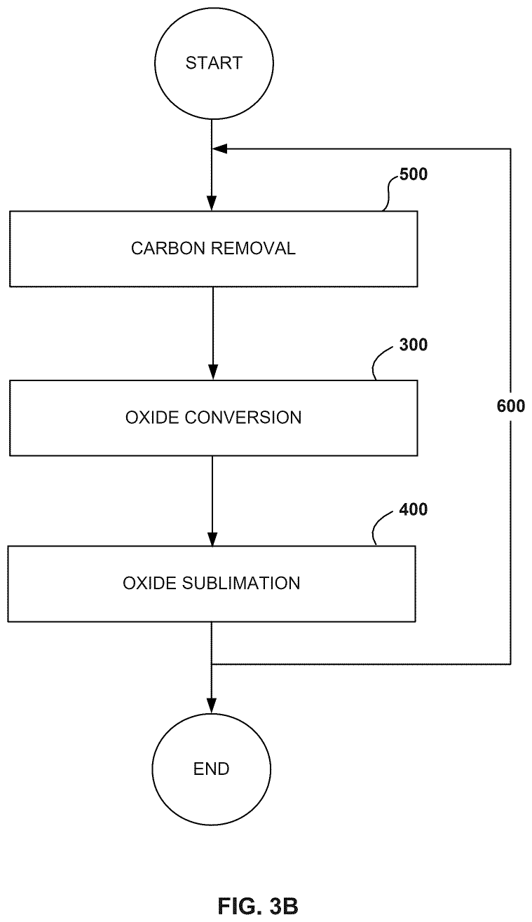

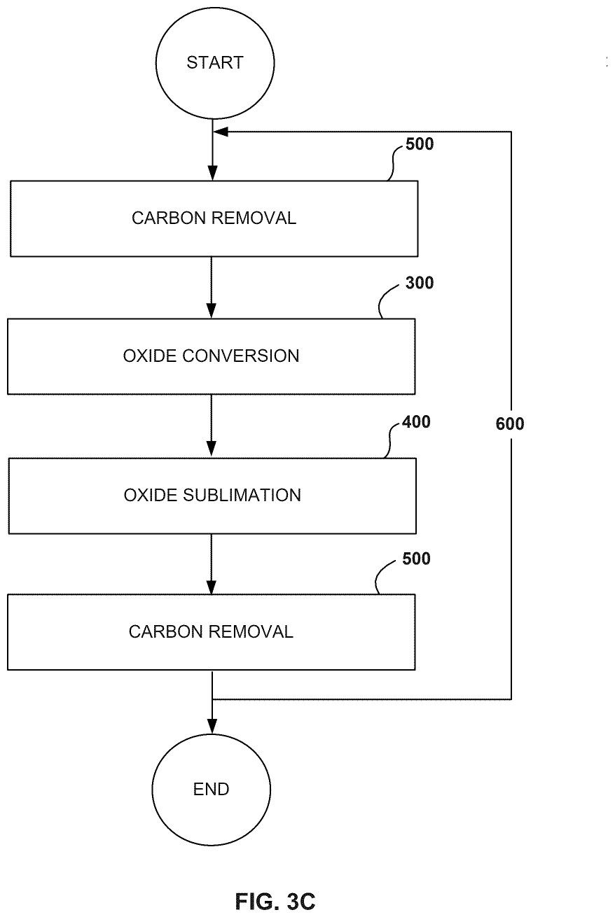

FIG. 3A illustrates a method in accordance with at least one embodiment of the invention. The method comprises an oxide conversion step 300, an oxide sublimation step 400, and a carbon removal step 500. Any of these steps or any combination of these steps may be repeated as needed. The entire method may be repeated through a repeat cycle 600.

FIG. 3B illustrates a method in accordance with at least one embodiment of the invention. The method comprises a carbon removal step 500, an oxide conversion step 300, and an oxide sublimation step 400. Any of these steps or any combination of these steps may be repeated as needed. The entire method may be repeated through a repeat cycle 600. The method of FIG. 3B differs from that of FIG. 3A in that the carbon removal step 500 comes before the oxide conversion step 300.

FIG. 3C illustrates a method in accordance with at least one embodiment of the invention. The method comprises a carbon removal step 500, an oxide conversion step 300, an oxide sublimation step 400, and a carbon removal step 500. Any of these steps or any combination of these steps may be repeated as needed. The entire method may be repeated through a repeat cycle 600. The method of FIG. 3C differs from that of FIG. 3B in that an additional carbon removal step 500 comes after the oxide sublimation step 400.

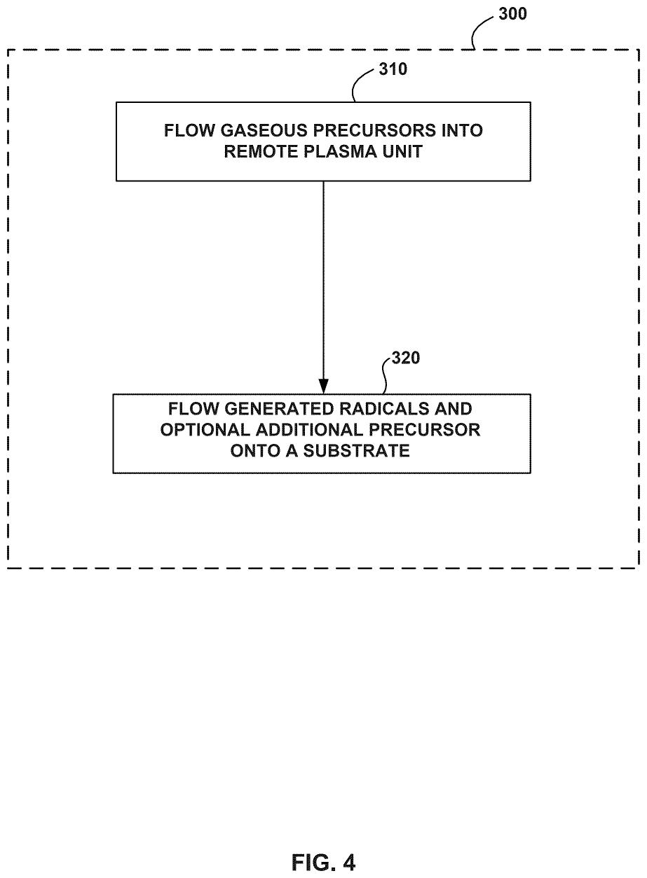

In accordance with at least one embodiment of the invention, the oxide conversion step 300 is illustrated in FIG. 4. The oxide conversion step 300 may comprises a step 310 of flowing gaseous precursors into a remote plasma unit and a step 320 of flowing generated radicals and an additional precursor onto a substrate. In accordance with at least one embodiment of the invention, the step 310 may comprise flow of argon, hydrogen, and NF₃ into the remote plasma unit. A flow of argon may range between 0.01 and 20 slm, between 0.1 and 10 slm, or between 1 and 8 slm. A flow of hydrogen may range between 10 sccm and 1500 slm, between 25 and 1200 slm, or between 50 sccm and 1000 slm. A flow of NF₃ may occur for a particular amount of time while the plasma is on in the remote plasma unit, ranging between 0.1 and 120 seconds, between 1 and 100 seconds, or between 5 and 80 seconds. The step 310 may comprise heating the reaction chamber 210 to a temperature between than 5 to 120° C., between than 5 to 80° C., or between than 5 to 60° C.

As a result of step 310, a gas of fluorine radicals is generated in the remote plasma unit. The fluorine radicals leave the remote plasma unit and may combine with an optional additional precursor gas in step 320 onto the substrate disposed in a reaction chamber. The optional additional precursor gas may comprise ammonia flowed at a rate ranging between 10 sccm and 1500 slm, between 25 and 1200 slm, or between 50 sccm and 1000 slm. The step 320 may comprise heating the reaction chamber 210 to a temperature between than 5 to 120° C., between than 5 to 80° C., or between than 5 to 60° C. The oxide conversion step 300 may result in a chemical reaction with oxides on a silicon germanium substrate having an oxide as follows:

NH₄F_{(g)}+SiGeOₓ₍ₛ₎→(NH₄)₂SiF₆₍ₛ₎+(NH₄)₂GeF₆₍ₛ₎+H₂O_{(g)}
As a result of the oxide conversion step 300, the oxide may be converted into a solid ammonium-hexafluorosilicate compound and a solid ammonium-hexafluorogermanate compound on the substrate.

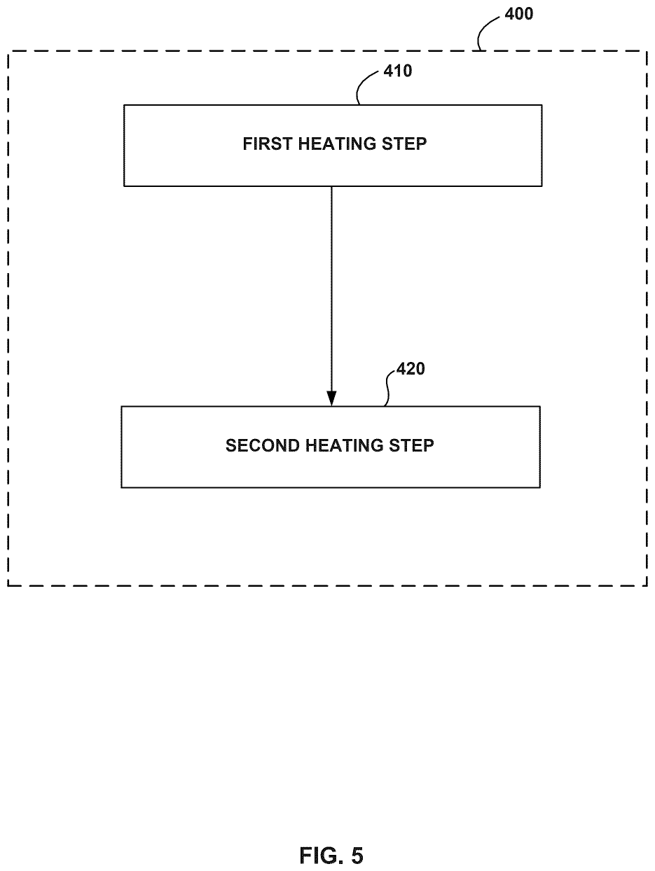

In accordance with at least one embodiment of the invention, the oxide sublimation step 400 is illustrated in FIG. 5. The oxide sublimation step 400 comprises a first heating step 410, or a second heating step 420, or both. The first heating step 410 may comprise heating the substrate to a temperature greater than 125° C., greater than 100° C., or greater than 90° C. The result of the first step 410 may be sublimation of the solid ammonium-hexafluorosilicate compound according to the following reaction:

(NH₄)₂SiF₆₍ₛ₎→NH_{3(g)}+HF_{(g)}+SiF_{4(g)}
The gaseous products may then be removed from the reaction chamber.

The second heating step 420 may comprise heating the substrate to a higher temperature than that of the first heating step 410. The temperature may be greater than 275° C., greater than 250° C., or greater than 225° C. To reach the high operation temperature, a high temperature showerhead may be designed to heat up to 250° C.-300° C. without heating up the reaction chamber. The result of the second step 420 may be sublimation of the solid ammonium-hexafluorogermanate compound according to the following reaction:

(NH₄)₂GeF₆₍ₛ₎→NH_{3(g)}+HF_{(g)}+GeF_{4(g)}
The gaseous products may then be removed from the reaction chamber.

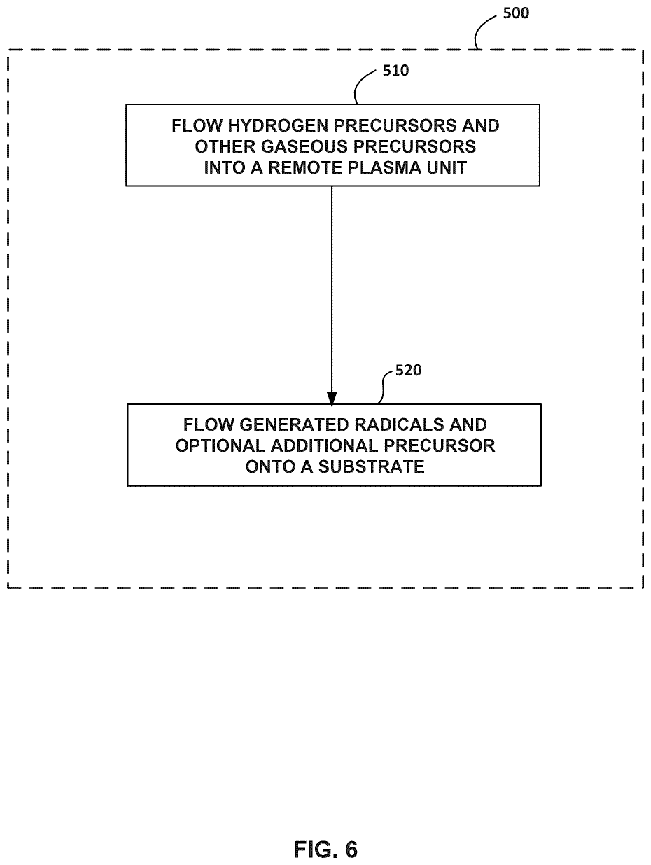

In accordance with at least one embodiment of the invention, the carbon removal step 500 is illustrated in FIG. 6. The carbon removal step 500 comprises a step 510 of flowing hydrogen precursors and other gaseous precursors into a remote plasma unit and a step 520 of flowing generated radicals and an optional additional precursor onto a substrate. The first heating step 510 may comprise flowing argon, hydrogen, and ammonia into the remote plasma unit. The gases may be flowed for a duration ranging between 0.1 and 180 seconds, between 1 and 120 seconds, or between 10 and 90 seconds. As a result, hydrogen radicals are generated in the remote plasma unit.

The step 520 takes the generated hydrogen radicals to react with carbon-based contaminants in the substrate. This step may happen at temperatures between 25° C. and 500° C., between 75° C. and 400° C., or between 150° C. and 300° C. A higher temperature showerhead may allow to heat up substrate and leading to effective removal of carbon. The result of the step 520 may be removal of the carbon according to the following reaction:

C₍ₛ₎+H*_{(g)}→CₓH_{y(g)}
Other reactions may include carbon with oxygen radicals. The gaseous products may then be removed from the reaction chamber.

The particular implementations shown and described are illustrative of the invention and its best mode and are not intended to otherwise limit the scope of the aspects and implementations in any way. Indeed, for the sake of brevity, conventional manufacturing, connection, preparation, and other functional aspects of the system may not be described in detail. Furthermore, the connecting lines shown in the various figures are intended to represent exemplary functional relationships and/or physical couplings between the various elements. Many alternative or additional functional relationship or physical connections may be present in the practical system, and/or may be absent in some embodiments.

It is to be understood that the configurations and/or approaches described herein are exemplary in nature, and that these specific embodiments or examples are not to be considered in a limiting sense, because numerous variations are possible. The specific routines or methods described herein may represent one or more of any number of processing strategies. Thus, the various acts illustrated may be performed in the sequence illustrated, in other sequences, or omitted in some cases.

The subject matter of the present disclosure includes all novel and nonobvious combinations and subcombinations of the various processes, systems, and configurations, and other features, functions, acts, and/or properties disclosed herein, as well as any and all equivalents thereof.

1. A method for processing a substrate comprising:
providing the substrate on a susceptor within a reaction chamber;
performing an oxide conversion step on the substrate, the oxide conversion step comprising: (1) flowing a first gas into a first remote plasma unit to form a first radical gas comprising fluorine radicals; and (2) flowing the first radical gas onto the substrate;
performing an oxide sublimation step on the substrate; and
performing a carbon removal step on the substrate, wherein the carbon removal step comprises flowing a second gas comprising hydrogen into a second remote plasma unit to form a second radical gas comprising hydrogen radicals, and flowing the second radical gas onto the substrate;
wherein a transport path connects the first remote plasma unit and the second remote plasma unit to the reaction chamber;
wherein the first remote plasma unit is dedicated for generating fluorine radicals and the second remote plasma unit is dedicated for generating hydrogen radicals.

2. The method of claim 1, wherein the transport path comprises a first coating comprising at least one of: atomic layer deposition (ALD)-formed aluminum oxide; plasma sprayed Al₂O₃; bare aluminum parts with native aluminum oxide; zirconium oxide (ZrO₂); lanthanum zirconium oxide (LZO); yttrium aluminum garnet (YAG); yttrium oxyfluoride (YOF); or yttrium oxide stabilized zirconium oxide (YSZ).

3. The method of claim 1, wherein the transport path comprises quartz material.

4. The method of claim 1, wherein the oxide sublimation step comprises: (1) a first heating step comprising heating the substrate to a temperature greater than 100° C.; and (2) after the first heating step, a second heating step comprising heating the substrate to a temperature greater than 250° C.

5. The method of claim 1, wherein the oxide conversion step, the oxide sublimation step, and the carbon removal step are each performed in the reaction chamber.

6. The method of claim 1, wherein the first gas comprises at least one of: NF₃, CF₄, C₂F₆, C₄F₆, C₄F₈, COF₂, SF₆, or WF₆.

7. The method of claim 1, wherein the second gas comprises at least one of: H₂, NH₃, or H₂O.

8. The method of claim 1, wherein the substrate comprises silicon germanium oxide, wherein the oxide conversion step converts the silicon germanium oxide to a solid ammonium-hexafluorosilicate and a solid ammonium-hexafluorogermanate.

9. The method of claim 8, wherein the oxide sublimation step comprises a first heating step comprising heating the substrate to a temperature greater than 125° C., and wherein the first heating step sublimates the solid ammonium-hexafluorosilicate.

10. The method of claim 9, wherein the oxide sublimation step comprises a second heating step comprising heating the substrate to a temperature greater than 275° C., and wherein the second heating step sublimates the solid ammonium-hexafluorogermanate.

11. A method for processing a substrate comprising:
providing the substrate on a susceptor within a reaction chamber, wherein the substrate comprises a first material comprising carbon;
performing a carbon removal step on the substrate, wherein the carbon removal step comprises producing hydrogen radicals in a second remote plasma unit and reacting the hydrogen radicals with carbon in the first material comprising carbon to produce gaseous hydrocarbons; and
after performing the carbon removal step, performing an oxide conversion step on the substrate, the oxide conversion step comprising: (1) flowing a first gas into a first remote plasma unit to form a first radical gas; and (2) flowing the first radical gas onto the substrate;
wherein a transport path connects the first remote plasma unit and the second remote plasma unit to the reaction chamber, and
wherein the first remote plasma unit is dedicated for generating fluorine radicals and the second remote plasma unit is dedicated for generating hydrogen radicals.

12. The method of claim 11, wherein the carbon removal step comprises heating the substrate to a temperature between 150° C. and 300° C.

13. The method of claim 11, wherein the substrate further comprises a second material comprising silicon germanium oxide, wherein the oxide conversion step converts the silicon germanium oxide to a solid ammonium-hexafluorosilicate and a solid ammonium-hexafluorogermanate, and wherein the oxide conversion step comprises a first heating step comprising heating the substrate to a temperature greater than 90° C. to sublimate the solid ammonium-hexafluorosilicate.

14. The method of claim 13, wherein the substrate further comprises a second material comprising silicon germanium oxide, wherein the oxide conversion step converts the silicon germanium oxide to a solid ammonium-hexafluorosilicate and a solid ammonium-hexafluorogermanate, and wherein the oxide conversion step comprises a second heating step comprising heating the substrate to a temperature greater than 225° C. to sublimate the solid ammonium-hexafluorogermanate.

15. The method of claim 11, wherein the first gas comprises at least one of: NF₃, CF₄, C₂F₆, C₄F₆, C₄F₈, COF₂, SF₆, or WF₆.

16. The method of claim 11, wherein the hydrogen radicals are formed from at least one of: H₂, NH₃, or H₂O.

17. The method of claim 11, wherein the transport path comprises a first coating comprising at least one of: atomic layer deposition (ALD)-formed aluminum oxide; plasma sprayed Al₂O₃; bare aluminum parts with native aluminum oxide; zirconium oxide (ZrO₂); lanthanum zirconium oxide (LZO); yttrium aluminum garnet (YAG); yttrium oxyfluoride (YOF); or yttrium oxide stabilized zirconium oxide (YSZ).

18. A method for processing a substrate comprising:
providing an apparatus comprising:
a reaction chamber;
a susceptor configured to hold a substrate;
a first gas source for providing a first gas;
a second gas source for providing a second gas;
a remote plasma unit configured to receive the first gas and produce a first radical gas;
a gas distribution device configured to flow the first radical gas and the second gas onto the substrate; and
a transport path connecting the remote plasma unit to the gas distribution device, wherein the first radical gas passes through the gas distribution device onto the substrate;
wherein the gas distribution device, the reaction chamber, the transport path, and the susceptor are coated with at least one of: lanthanum zirconium oxide (LZO); yttrium aluminum garnet (YAG); yttrium oxyfluoride (YOF); or yttrium oxide stabilized zirconium oxide (YSZ);
performing an oxide conversion step on the substrate, the oxide conversion step comprising: (1) flowing the first gas into the remote plasma unit to form the first radical gas; and (2) flowing the first radical gas onto the substrate; and
performing a carbon removal step on the substrate, wherein the carbon removal step comprises flowing the second gas into the remote plasma unit to form a second radical gas;
wherein the first radical gas comprises F radicals, and
wherein the second radical gas comprises H radicals.

19. The method of claim 18, further comprising performing an oxide sublimation step on the substrate, the oxide sublimation step comprising: (1) a first heating step comprising heating the substrate to a temperature greater than 100° C.; and (2) after the first heating step, a second heating step comprising heating the substrate to a temperature greater than 250° C.

20. The method of claim 18, wherein the transport path further comprises quartz material.
